(19) United States
(12) Patent Application Publication
(10) Pub. No.: US 2012/0097104 A1
(43) Pub. Date: Apr. 26, 2012

(54) RF IMPEDANCE MATCHING NETWORK WITH SECONDARY DC INPUT

(75) Inventors: John A. Pipitone, Livermore, CA (US); Gerald E. Boston, Glenwood Springs, CO (US)

(73) Assignee: COMET TECHNOLOGIES USA, INC., San Jose, CA (US)

(21) Appl. No.: 12/908,727

(22) Filed: Oct. 20, 2010

(51) Int. Cl. C23C 16/503; H02J 3/02

(52) U.S. Cl. 118/723 E; 307/2

(57) ABSTRACT

Embodiments of the disclosure may provide a matching network for a physical vapor deposition system. The matching network may include an RF generator coupled to a first input of an impedance matching network, and a DC generator coupled a second input of the impedance matching network. The impedance matching network may be configured to receive an RF signal from the RF generator and a DC signal from the DC generator and cooperatively communicate both signals to a deposition chamber target through an output of the impedance matching network. The matching network may also include a filter disposed between the second input and the output of the impedance matching network.

### BACKGROUND

In forming semiconductor devices, thin films are often deposited using physical vapor deposition (“PVD”) or “sputtering” in a vacuum deposition chamber. Traditional PVD uses an atom of an inert gas, e.g. argon, ionized by an electric field and low pressure to bombard a target material. Released by the bombardment of the target with the inert gas, a neutral target atom travels to a semiconductor substrate and forms a thin film in conjunction with other atoms from the target. Ionizing the atoms released from the target, as in an ionized PVD (“iPVD”) process, further allows for some level of control over the deposition process, e.g., controlling the directionality of the target atom allows for more efficient film thickness over features and for more effective gap fill.

In conventional PVD systems, however, ion bombardment of the target material is often times limited, and the deposition process often times lacks predictable uniformity. What is needed, therefore, is a system and method for increasing the ion bombardment of the target in a physical vapor deposition chamber, while also providing for controllable uniform deposition.

### SUMMARY

Embodiments of the disclosure may provide a matching network for a physical vapor deposition system. The matching network may include an RF generator coupled to a first input of an impedance matching network, and a DC generator coupled a second input of the impedance matching network. The impedance matching network may be configured to receive an RF signal from the RF generator and a DC signal from the DC generator and cooperatively communicate both signals to a deposition chamber target through an output of the impedance matching network. The matching network may also include a filter disposed between the second input and the output of the impedance matching network.

Embodiments of the disclosure may further provide a matching network for a physical vapor deposition system. The matching network may include a first RF generator coupled to a deposition target through a first input to a first impedance matching network. The first RF generator may be configured to introduce a first RF signal to the deposition target. The matching network may also include a DC generator coupled to the deposition chamber target through a second input to the first impedance matching network. The DC generator may be configured to introduce a DC signal to the deposition chamber target. The matching network may further include a second RF generator coupled to a deposition chamber pedestal through a second impedance matching network and configured to introduce a second RF signal to the deposition chamber pedestal, and a gas supply disposed in a deposition chamber wall and configured to facilitate formation of a plasma between the deposition chamber lid and the deposition chamber pedestal. A filter may be disposed between the second input and a single output of the first impedance matching network and may be configured to filter out one or more RF frequencies from the first RF signal.

Embodiments of the disclosure may further provide a method of introducing an RF signal and a DC signal to a physical vapor deposition target. The method may include introducing an RF signal to a location on a deposition chamber target of a physical vapor deposition system through an impedance matching network and introducing a DC signal from a DC generator to the same location on the target through the impedance matching network. The method may further include filtering out one or more RF signal frequencies leaked toward the DC generator from the chamber.

### BRIEF DESCRIPTION OF THE DRAWINGS

The present disclosure is best understood from the following detailed description when read with the accompanying Figures. It is emphasized that, in accordance with the standard practice in the industry, various features are not drawn to scale. In fact, the dimensions of the various features may be arbitrarily increased or reduced for clarity of discussion.

FIG. 1 is a schematic of an exemplary physical vapor deposition system, according to one or more embodiments of the disclosure.

FIG. 2 is a schematic of an exemplary physical vapor deposition system having a dual input impedance matching network, according to one or more embodiments of the disclosure.

FIG. 3 is a schematic of an exemplary DC filter, according to one or more embodiments of the disclosure.

FIG. 4 is a flowchart of an exemplary method for introducing an RF signal and a DC signal to a physical vapor deposition system, according to one or more embodiments of the disclosure.

### DETAILED DESCRIPTION

It is to be understood that the following disclosure describes several exemplary embodiments for implementing different features, structures, or functions of the invention. Exemplary embodiments of components, arrangements, and configurations are described below to simplify the present disclosure; however, these exemplary embodiments are provided merely as examples and are not intended to limit the scope of the invention. Additionally, the present disclosure may repeat reference numerals and/or letters in the various exemplary embodiments and across the Figures provided herein. This repetition is for the purpose of simplicity and clarity and does not in itself dictate a relationship between the various exemplary embodiments and/or configurations discussed in the various Figures. Moreover, the formation of a first feature over or on a second feature in the description that follows may include embodiments in which the first and second features are formed in direct contact, and may also include embodiments in which additional features may be formed interposing the first and second features, such that the first and second features may not be in direct contact. Finally, the exemplary embodiments presented below may be combined in any combination of ways, i.e., any element from one exemplary embodiment may be used in any other exemplary embodiment, without departing from the scope of the disclosure.

Additionally, certain terms are used throughout the following description and claims to refer to particular components. As one skilled in the art will appreciate, various entities may refer to the same component by different names, and as such, the naming convention for the elements described herein is not intended to limit the scope of the invention, unless otherwise specifically defined herein. Further, the naming convention used herein is not intended to distinguish between components that differ in name but not function. Additionally, in the following discussion and in the claims, the terms “including” and “comprising” are used in an open-ended fashion, and thus should be interpreted to mean “including, but not limited to.” All numerical values in this disclosure may be exact or approximate values unless otherwise specifically stated. Accordingly, various embodiments of the disclosure may deviate from the numbers, values, and ranges disclosed herein without departing from the intended scope. Furthermore, as it is used in the claims or specification, the term “or” is intended to encompass both exclusive and inclusive cases, i.e., “A or B” is intended to be synonymous with “at least one of A and B,” unless otherwise expressly specified herein.

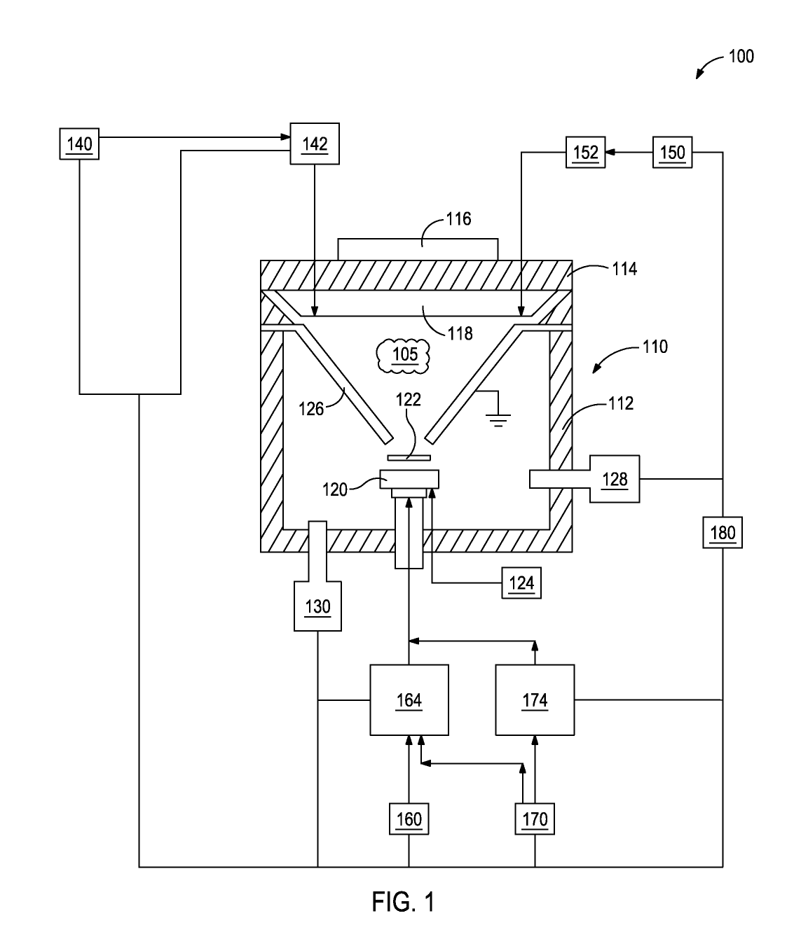

FIG. 1 is a schematic of an exemplary PVD system 100 of the disclosure. The PVD system 100 includes a chamber 110 having a chamber body 112 and a lid or ceiling 114. A magnet assembly 116 is at least partially disposed on a second or “upper” side of the lid 114. The magnet assembly 116 may be, but is not limited to, a fixed permanent magnet, a rotating permanent magnet, a magnetron, an electromagnet, or any combination thereof. In at least one embodiment, the magnet assembly 116 may include one or more permanent magnets disposed on a rotatable plate that is rotated by a motor between about 0.1 and about 10 revolutions per second. For example, the magnet assembly 116 may rotate counter-clockwise at about 1 revolution per second.

A target 118 is generally positioned on a first or “lower” side of the lid 114 generally opposite the magnet assembly 116. The target 118 may be at least partially composed of, but is not limited to, single elements, borides, carbides, fluorides, oxides, silicides, selenides, sulfides, tellerudes, precious metals, alloys, intermetallics, or the like. For example, the target 118 may be composed of copper (Cu), silicon (Si), titanium (Ti), tantalum (Ta), tungsten (W), aluminum (Al), or any combination or alloy thereof.

A pedestal 120 may be disposed in the chamber 110 and configured to support a wafer or substrate 122. In at least one embodiment, the pedestal 120 may be or include a chuck configured to hold the substrate 122 to the pedestal 120. For example, the pedestal 120 may include a mechanical chuck, a vacuum chuck, an electrostatic chuck (“e-chuck”), or any combination thereof, for holding the substrate 122 to the pedestal 120. Mechanical chucks may include one or more clamps to secure the substrate to the pedestal 120. Vacuum chucks may include a vacuum aperture (not shown) coupled to a vacuum source (not shown) to hold the substrate 122 to the pedestal 120. E-chucks rely on the electrostatic pressure generated by an electrode energized by a direct current (“DC”) voltage source to secure the substrate 122 to the chuck. In at least one embodiment, the pedestal 122 may be or include an e-chuck powered by a DC power supply 124.

A shield 126 may at least partially surround the pedestal 120 and the substrate 122 to intersect any direct path between the target 118 and the chamber body 112. The shield 126 may be generally cylindrical or frusto-conical, as shown. The shield 126 is generally electrically grounded, for example, by physical attachment to the chamber body 112. Sputter particles travelling from the target 118 toward the chamber body 112 may be intercepted by the shield 126 and deposit thereon. The shield 126 may eventually build up a layer of the sputtered material and require cleaning to maintain acceptable chamber particle counts. The use of the shield 126 may reduce the expense of reconditioning the chamber 110 to reduce particle count.

A gas supply 128 may be coupled to the chamber 110 and configured to introduce a controlled flow of selected gases into the chamber 110. Gas introduced to the chamber 110 may include, but is not limited to, argon (Ar), nitrogen (N₂), helium (He), xenon (Xe), hydrogen (H₂), or any combination thereof.

A vacuum pump 130 may be coupled to the chamber 110 and configured maintain a desired sub-atmospheric pressure or vacuum level in the chamber 110. In at least one embodiment, the vacuum pump 130 may maintain a pressure of between about 1 and about 100 millitorrs in the chamber 110. Both the gas supply 128 and the vacuum pump 130 are at least partially disposed through the chamber body 112.

A first radio frequency (“RF”) generator 140 is generally coupled to the target 118 of the chamber 110 through a first impedance matching network 142. The first RF generator 140 is configured to introduce a first RF or AC signal to the target 118. The first RF generator 140 may have a frequency ranging from 300 hertz (“Hz”) to 162 megahertz (“MHz”).

In at least one embodiment, a DC generator 150 may supply or introduce a DC signal to the chamber 110. For example, the DC generator 150 may supply a DC signal to the target 118. The DC signal is generally supplied to a different location on the target 118 than the first RF signal from the first RF generator 140. For example, the DC signal may be supplied on an opposite side of the target 118 than the first RF signal from the first RF generator 140. A DC filter 152 may be coupled to the DC generator 150 and configured to prevent RF signals, e.g. from the first RF generator 140, from reaching and damaging the DC generator 150. The DC generator 150 is generally configured to increase ionic bombardment of the target 118 by increasing the voltage differential between the target 118 and the pedestal 120 and/or the rest of the chamber 110.

A second RF generator 160 is generally coupled to the pedestal 120 through a second impedance matching network 162. The second RF generator 160 is configured to introduce a second RF signal to the pedestal 120 to bias the pedestal 120 and/or the chamber 110. The second impedance matching network 162 may be the same as the first impedance matching network 142, or it may be different, as desired. The second RF generator 160 may have a frequency ranging from 300 Hz to 162 MHz.

In at least one embodiment, a third RF generator 170 may also be coupled to the pedestal 120 through a third impedance matching network 172 or through the second impedance matching network 162 to further control the bias of the pedestal 120. The third impedance matching network 172 may be the same as the first and/or second impedance matching networks 142, 162, or it may be different, as desired. Although not shown, one or more additional RF generators and corresponding impedance matching networks may be combined or used with the second and third RF generators 160, 170 and the second and/or third impedance matching networks 162, 172.

Current supplied to the chamber 110 via the first RF generator 140, the second RF generator 160, the third RF generator 170, the DC generator 150, or any combination thereof, cooperatively ionizes atoms in the inert gas supplied by the gas supply 128 to form a plasma 105 in the chamber 110. The plasma 105, for example, may be a high density plasma. The plasma 105 includes a plasma sheath (not shown), which is a layer in the plasma 105 which has a greater density of positive ions, and hence an overall excess positive charge, that balances an opposite negative charge on the surface of a the target 118

A system controller 180 may be coupled to one or more gas supplies 128, the vacuum pump 130, the RF generators 140, 160, 170, and the DC generator 150. In at least one embodiment, the system controller 180 may also be coupled to one or more of the impedance matching networks 142, 162, 172. The system controller 180 may be configured to the control the various functions of each component to which it is coupled. For example, the system controller 180 may be configured to control the rate of gas introduced to the chamber 110 from the gas supply 128. The system controller 180 may be configured to adjust the pressure within the chamber 110 with the vacuum pump 130. The system controller 180 may be configured to adjust the output signals from the RF generators 140, 160, 170, and/or the DC generator 150. In at least one embodiment, the system controller 180 may be configured to adjust the impedances of the impedance matching networks 142, 162, 172.

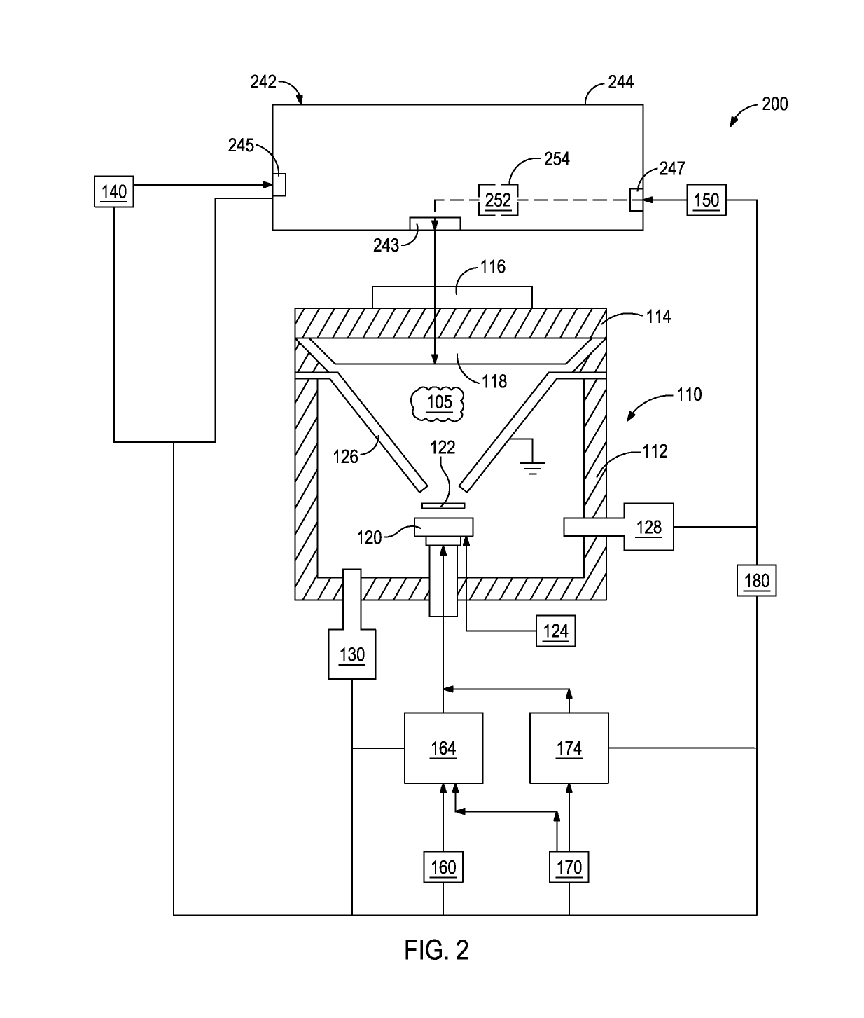

Referring now to FIG. 2, depicted is another exemplary PVD system 200 of the disclosure having a dual input impedance matching network 242. The PVD system 200 is similar in some respects to the PVD system 100 described above in FIG. 1. Accordingly, the system 200 may be best understood with reference to FIG. 1, wherein like numerals correspond to like components and therefore will not be described again in detail.

Unlike in the system 100, however, in the system 200 the RF generator 140 and the DC generator 150 may be coupled to a single point on the target 118 through a dual input RF impedance matching network 242. For example, the dual input RF impedance matching network 242 may output a combined DC and RF signal that is connected at or near the center the target 118 (backside). By coupling the DC generator 150 through the dual input RF impedance matching network 242, RF and DC input signals may be applied simultaneously to the target 118 at the same location to provide a single source feed to the chamber 110. A single source feed to the chamber 110 may increase uniformity of the ion deposition of the substrate 122.

In at least one embodiment, a DC filter 252 is disposed within the dual input RF impedance matching network 242 and is configured to protect the DC generator 150 from reflected or other RF frequencies that could damage the DC generator 150. For example, the DC filter 252 may be configured to filter out a fundamental frequency of the first RF signal from the first RF generator 140 and/or associated harmonics of the fundamental frequency (e.g. second and third harmonics). The DC filter 252 may protect the input of the DC generator 150 from harmful RF frequencies residing within the dual input RF impedance matching network 242 and/or RF frequencies leaking into the output of the dual input impedance matching network 242 from the chamber 110.

The dual input impedance matching network 242 may include a first enclosure 244 having matching circuitry (not shown) and the DC filter 252 disposed therein. The first enclosure 244 may include two or more openings or inputs (two are shown 245, 247) for the first RF signal from the first RF generator 140 and the DC signal from the DC generator 150. For example, the first RF signal from the first RF generator 140 may be introduced to the dual input impedance matching network 242 through a first opening 245, and the DC signal may be introduced to the dual input impedance matching network 242 through a second opening 247. The first enclosure 244 may also include a third opening or output 243 for a single/combined output for both the DC signal from the DC generator 150 and the first RF signal from the first RF generator 140. For example, the dual input impedance matching network 242 can introduce both the DC signal from the DC generator 150 and the first RF signal from the first RF generator 140 from the output 243 to a single location on the target 118.

A second enclosure 254 may be positioned inside the first enclosure 244 and have the DC filter 252 disposed therein. The second enclosure 254 is physically configured to isolate the DC filter 252 from the RF frequencies in the first enclosure associated with the dual input impedance matching network 242, e.g. harmful RF frequencies in the first RF signal from the first RF generator 140. For example, the second enclosure 254 may include a shielded box disposed around the DC filter 252, wherein the box is specifically shielded to block RF signals or other interference generated by the adjacent components positioned within or proximate to the first enclosure 244. The shielded box may protect the DC filter 252 from interference, intermodulation, and/or harmonic distortion that could interfere with the operation of filter circuits therein. In at least one embodiment, the shielded box includes vent holes (not shown) configured to prevent overheating of the DC filter 252 and/or other components therein, while still blocking harmful or interfering RF signals from reaching the DC filter 251. For example, the vent holes may be sized, shaped, and/or positioned to allow for air circulation into/out of the shielded box, while still preventing or blocking RF frequencies present in the first enclosure for the dual input RF impedance matching network 242 from passing therethrough.

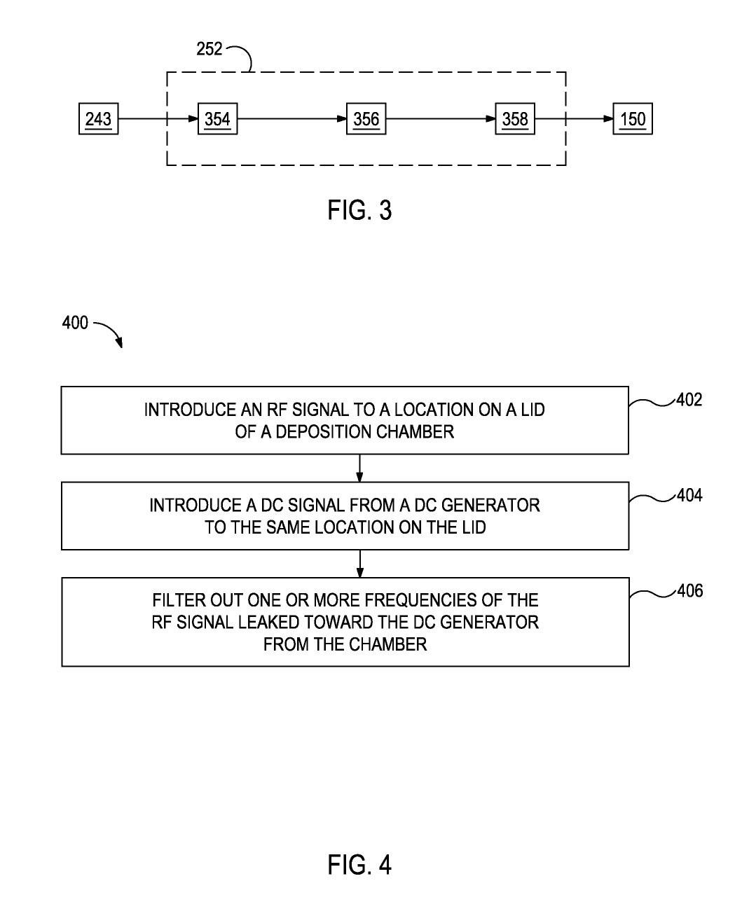

FIG. 3 is a schematic of an exemplary DC filter 252 depicted in FIG. 2. The DC filter 252 is disposed at the output 243 of the dual input RF impedance matching network 242 and is coupled to the DC generator 150 proximate one of the inputs 245, 247 to the dual input RF impedance matching network 242. The DC filter 252 is a multistage filter including one or more filter stages (three are shown 354, 356, 358), where the selected filter stages each filter out one or more predetermined frequencies. For example, each filter stage of the DC filter 252 may filter out a different frequency, e.g. the fundamental frequency of the first RF generator 140 or a harmonic of the fundamental frequency.

In at least one embodiment, the DC filter 252 includes a first filter stage 354, a second filter stage 356, and a third filter stage 358, each connected in series. Each filter stage 354, 356, 358 may be the same type of filter or may be different, as desired. In at least one embodiment, all three stages 354, 356, 358 may be resonant traps. For example, the first filter stage 354 targets the fundamental frequency of the first RF generator 140, the second filter stage 356 targets a second harmonic of the fundamental frequency, and the third filter stage 358 targets a third harmonic of the fundamental frequency. In at least one embodiment, the first stage 354 is a resonant trap targeted at the fundamental frequency of the first RF generator 140, the second stage 356 is a resonant trap, a low-pass filter, or any combination thereof, targeted at the second harmonic of the fundamental frequency, and the third stage 358 is a resonant trap, a low-pass filter, or any combination, thereof targeted at the third harmonic of the fundamental frequency.

The stages of the DC filter 252 can be specifically designed to filter out frequencies from the first RF generator 140 and/or other frequencies in the chamber 110. For example, the design and/or choice of components of each filter stage 354, 356, 358 may change if the first RF generator 140 operates at a different fundamental frequency. The number of stages of the DC filter 252 may also vary, as desired, to target more or different fundamental frequencies. For example, a fourth or fifth stage (not shown) may be added to filter out more harmonics of the fundamental frequency or other resonant frequencies introduced by the second and third RF generators 160, 170.

Referring to FIG. 4, with continuing reference to FIGS. 1-3, illustrated is a flowchart of an exemplary method 400 for introducing an RF signal and a DC signal to a PVD system 200. In operation, the first RF signal from the first generator 140 is introduced to a location on the lid 114 and/or the target 118 of the chamber 110, as at 402. The DC signal from the DC generator 150 is introduced to the same location on the lid 114 and/or the target 118, as at 404. The first RF signal and the DC signal are both introduced to the lid 114 and/or the target 118 through the dual input RF impedance matching network 242. In at least one embodiment, the power applied to the target 118 may be from about 5 kilowatts to about 60 kilowatts.

A bias is applied to the pedestal 120 by the second RF generator 160 and/or the third RF generator 170. In at least one embodiment, a second RF signal is introduced to the pedestal 120 through a second impedance matching network 162 to bias the pedestal 120. In at least one embodiment, a third RF signal from the third RF generator 170 is introduced to the pedestal 120 through the second impedance matching network 162 or through a third impedance matching network 172. The bias creates a voltage differential between the target 118 and the remainder of the chamber 110.

Gas, e.g. generally an inert gas, is introduced into the chamber 110 from the gas supply 128 to facilitate formation of the plasma 105 within the chamber 110. Neutral atoms of the gas are ionized, giving off electrons, and the voltage differential between the target 118 and the pedestal 110 causes the electrons to impact other neutral atoms of the gas, creating more electrons and ionized atoms. This process is repeated so that the plasma 105, including electrons, ionized atoms, and neutral atoms, exists within the chamber 110.

The ionized atoms, which are positively charged, are attracted and therefore accelerated towards the target 118, which is negatively charged. The magnitude of the voltage differential in the chamber 110 controls the force and/or speed with which the atoms of the gas are attracted to the target 118. The DC generator 150 can increase the voltage differential by applying a DC voltage via the DC signal to the target 118, thereby increasing ion bombardment of the target 118.

Upon impact with the target 118, energy of the ionized atoms dislodges and ejects one or more atoms from the target material. Some energy from the ionized gas may be transferred to the target 118 in the form of heat. The dislodged atoms become ionized, like the neutral atoms, by impacting the electrons in the plasma 105. Once ionized, the released atoms are generally urged toward the substrate 122 via magnetic field paths generated inside the chamber 110 to form a sputtered layer of the target material on the substrate 122. The magnetic field present in the chamber 110 may be at least partially controlled by the magnet 118 disposed on the lid 112 of the chamber 110. Uniformity of the ion deposition on the substrate may be increased by applying the DC voltage from the DC generator to the same point on the target 118 as the first RF signal from the first RF generator 140.

Each of the impedance matching networks 242, 162, 172 may be adjusted (offline or during operation of the chamber in some embodiments) so that the combined impedances of the chamber 110 and the respective impedance matching networks 142, 162, 172 match the impedance of the respective RF generators 140, 160, 170 to efficiently transmit RF energy from the RF generators 140, 160, 170 to the chamber 110 rather than being reflected back to the RF generators 140, 160, 170. For example, the dual input RF impedance matching network 242 may be adjusted so that the combined impedance of the chamber 110 and the impedance of the dual input RF impedance matching network 242 matches the impedance of the first RF generator 140, thereby preventing RF energy from being reflected back to the first RF generator 140.

The chamber 110 may reflect or “leak” frequencies of the RF signals back towards the DC generator 150. In at least one embodiment, the filter 252 disposed in the dual input RF impedance matching network 242 filters out one or more of the frequencies of the first RF signal from the first RF generator 140 leaked toward the DC generator from the chamber 110, as at 406. The filter 252 may be specifically configured to filter out frequencies that are known to be destructive to the DC generator 150.

In at least one embodiment, the first filter stage 354 of the DC filter 252 may filter out one or more frequencies of the first RF signal from the RF generator 140. For example, the first filter stage 354 may be a resonant trap or notch filter that rejects a frequency band at or including the fundamental frequency of the first RF signal from the RF generator 140, thereby filtering out the fundamental frequency. Once the fundamental frequency has been filtered out, the second filter stage 356 may filter out another frequency, e.g. one of the harmonics of the fundamental frequency. For example, the second filter stage 356 may include another resonant trap and/or a low pass filter to filter out the second harmonic of the fundamental frequency of the first RF signal from the RF generator 140. The third filter stage 358 may filter out another frequency of the first RF signal from RF generator 140 not already filtered out by the previous two stages. For example, the third filter stage 358 may include a third resonant trap and/or another low pass filter to filter out the third harmonic of the fundamental frequency of the first RF signal from RF generator 140.

Although the first filter stage 354, the second filter stage 356, and the third filter stage 358 are depicted in series, the order and configuration may vary without departing from the scope of the disclosure. For example, the second filter stage 356 may filter out one of the harmonics of the fundamental frequency prior to the first stage 354 filtering out the fundamental frequency.

The foregoing has outlined features of several embodiments so that those skilled in the art may better understand the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

We claim:

1. A matching network for a physical vapor deposition system, comprising:
an RF generator coupled to a first input of an impedance matching network;
a DC generator coupled a second input of the impedance matching network, wherein the impedance matching network is configured to receive an RF signal from the RF generator and a DC signal from the DC generator and cooperatively communicate both signals to a deposition chamber target through an output of the impedance matching network; and
a filter disposed between the second input and the output of the impedance matching network.

2. The matching network of claim 1, wherein the filter is configured to prevent one or more RF frequencies from reaching the DC generator.

3. The matching network of claim 2, wherein filter is a multistage filter.

4. The matching network of claim 3, wherein filter comprises:
a first filter stage configured to filter out a first frequency;
a second filter stage coupled to the first filter stage, the second filter stage configured to filter out a second frequency; and
a third filter stage coupled to the second filter stage, the third filter stage configured to filter out a third frequency, wherein the first, second, and third frequencies are different.

5. The matching network of claim 4, wherein the first frequency is a fundamental frequency of the RF signal, the second frequency is a second harmonic of the fundamental frequency, and the third frequency is a third harmonic of the fundamental frequency.

6. The matching network of claim 5, wherein the first, second, and third filter stages each comprise resonant traps

7. The matching network of claim 5, wherein the first filter stage comprises a first resonant trap, the second filter stage comprises a first low pass filter, and the third filter stage comprises a second low pass filter.

8. The matching network of claim 1, wherein the impedance matching network comprises a first enclosure having a first opening for the first input, a second opening for the second input, and a third opening for a single output.

9. The matching network of claim 8, wherein the filter is disposed in an RF shielded enclosure.

10. The matching network of claim 9, wherein the RF shielded enclosure is disposed in the first enclosure and is configured to protect the filter from interference, intermodulation, and harmonic distortion.

11. A matching network for a physical vapor deposition system, comprising:
a first RF generator coupled to a deposition target through a first input to a first impedance matching network, wherein the first RF generator is configured to introduce a first RF signal to the deposition target;
a DC generator coupled to the deposition chamber target through a second input to the first impedance matching network, wherein the DC generator is configured to introduce a DC signal to the deposition chamber target;
a second RF generator coupled to a deposition chamber pedestal through a second impedance matching network and configured to introduce a second RF signal to the deposition chamber pedestal;
a gas supply disposed in a deposition chamber wall and configured to facilitate formation of a plasma between the deposition chamber lid and the deposition chamber pedestal; and
a filter disposed between the second input and a single output of the first impedance matching network, wherein the filter is configured to filter out one or more RF frequencies from the first RF signal.

12. The matching network of claim 11, wherein the first RF generator and the DC generator are coupled to the deposition chamber target through the single output of the first impedance matching network.

13. The matching network of claim 11, wherein the single output of the first impedance matching network is coupled to the center of the deposition chamber target.

14. The matching network of claim 11, further comprising a third RF generator coupled to the deposition chamber pedestal through a third impedance matching network.

15. A method of introducing an RF signal and a DC signal to a physical vapor deposition target, comprising:
introducing an RF signal to a location on a deposition chamber target of a physical vapor deposition system through an impedance matching network;
introducing a DC signal from a DC generator to the same location on the target through the impedance matching network; and
filtering out one or more RF signal frequencies leaked toward the DC generator from the chamber.

16. The method of claim 15, wherein filtering out one or more RF signal frequencies comprises filtering out a fundamental frequency of the RF signal with a filter disposed in the path.

17. The method of claim 16, wherein the fundament frequency is filtered out with a resonant trap included in the filter.

18. The method of claim 16, wherein filtering further comprises filtering out a second harmonic of the fundamental frequency and filtering out a third harmonic of the fundamental frequency with the filter.

19. The method of claim 18, wherein the second harmonic is filtered out with a first resonant trap, a first low pass filter, or a combination thereof, and wherein the third harmonic is filtered out with second resonant trap, a second low pass filter, or a combination thereof.

20. The method of claim 15, wherein the RF signal and the DC signal are introduced the center of the deposition chamber target to facilitate uniform deposition of a substrate.
